(19) United States
(12) Patent Application Publication
(10) Pub. No.: US 2019/0239354 A1
(43) Pub. Date: Aug. 1, 2019

(54) METAL PAD INTERFACE

(71) Applicant: JOINSET CO., LTD., Ansan-si (KR)

(72) Inventor: Sun-Ki Kim, Gunpo-si (KR)

(73) Assignee: JOINSET CO., LTD.

(21) Appl. No.: 16/380,001

(22) Filed: Apr. 10, 2019

Related U.S. Application Data
(63) Continuation of application No. PCT/KR2018/000211, filed on Jan. 4, 2018.

(30) Foreign Application Priority Data
Jan. 6, 2017 (KR) 10-2017-0002631

(51) Int. Cl. H05K 1/11; H05K 1/02

(52) U.S. Cl. CPC H05K 1/116; H05K 1/0278

(57) ABSTRACT

A metal pad interface configured to be soldered to an electrically conductive object to provide reliable electrical connection between the electrically configuration object and another electrically conductive object. The metal pad interface includes: a body including a core formed of copper or a copper alloy and a nickel-plating layer formed on an entire surface of the core; an upper contact portion formed on an upper surface of the body by plating the upper surface of the body with gold or a gold alloy; and a lower contact portion formed on a lower surface of the body by plating the lower surface of the body with gold or a gold alloy, wherein the lower contact portion is mounted on a divided land pattern of a circuit board by soldering to cover the divided land pattern, and an electrically conductive external object is electrically connected to the upper contact portion by bringing the object into contact with the upper contact portion.

### REFERENCE TO RELATED APPLICATIONS

This is a continuation of pending International Patent Application PCT/KR2018/000211 filed on Jan. 4, 2018, which designates the United States and claims priority of Korean Patent Application No. 10-2017-002631 filed on Jan. 6, 2017, the entire contents of which are incorporated herein by reference.

### FIELD OF THE INVENTION

The present invention relates to a metal pad interface, and more particularly, to a metal pad interface configured to be soldered to an electrically conductive object to provide reliable electrical connection between the electrically configuration object and another electrically conductive object.

### BACKGROUND OF THE INVENTION

In general, an external electronic component such as an antenna is electrically connected to a conductive pattern of a printed circuit board by bring the external electronic component into electrical contact with a land pattern which has a relatively large area and is formed on an end of the conductive pattern of the printed circuit board.

However, since the land pattern is formed of a copper material, the possibility of corrosion of the land pattern is high when the land pattern is exposed to the outside, and if the land pattern corrodes, it may be difficult to provide reliable electrical contact between an external electronic component and the land pattern.

To solve this problem, the land pattern may be continuously plated with nickel and gold to form corrosion-resistant plating layers thereon.

However, such land patterns formed on a circuit board are not only few in number but also scattered, and thus partial plating is required. In this case, other problems such as difficulty in plating and high manufacturing costs may arise.

To address this, conductive patterns including all land patterns may be entirely plated with nickel and gold. However, this method incurs much more manufacturing costs.

In addition, since copper used to form land patterns has relatively low strength, if land patterns are repetitively brought into elastic contact with high-strength electrical contact terminals for a long time, reliable electrical contact may not be maintained due to abrasion of the land patterns.

### SUMMARY OF THE INVENTION

Therefore, an object of the present invention is to provide a metal pad interface that can economically provide reliable electrical contact between an electrically conductive external object and a conductive pattern of a circuit board.

Another object of the present invention is to provide a metal pad interface configured to guarantee reliable electrical contact for land patterns scattered on a circuit board.

Another object of the present invention is to provide a metal pad interface configured to impart mechanical strength to a land pattern formed of copper having relatively low mechanical strength for guaranteeing long-term reliable electrical contact between the land pattern and an electrically conductive counterpart.

Another object of the present invention is to provide a metal pad interface configured to prevent rising of molten solder during soldering.

Another object of the present invention is to provide a metal pad interface that can substantially provide the effect of gold plating for a land pattern without having to perform a gold plating process for corrosion resistance.

To accomplish the above objects, a metal pad interface includes: a body including a sheet-shaped metal core and a nickel-plating layer formed on an outer surface of the core; an upper contact portion formed on an upper surface of the body by plating the upper surface of the body with gold or a gold alloy; and a lower contact portion formed on a lower surface of the body by plating the lower surface of the body with gold or a gold alloy, wherein edges of the body extend outward more than edges of the upper contact portion, wherein the lower contact portion is mounted on a land pattern of a circuit board by soldering, and the upper contact portion is brought into elastic contact with an electrically conductive external object for electrical connection between the object and the land pattern, wherein the nickel-plating layer prevents molten solder from rising along the upper contact portion during the soldering.

Preferably, the edges of the body may extend outward more than edges of the lower contact portion.

Preferably, the upper and lower contact portions may have the same size and shape or similar sizes and shapes, and may include the same material.

Preferably, the upper contact portion may have greater mechanical strength than the land pattern.

Preferably, the core may include copper, a copper alloy, or stainless steel.

To accomplish the above objects, an electrical contact structure for a circuit board includes a metal pad interface which is soldered to a land pattern of the circuit board by reflow soldering, wherein the metal pad interface includes: a body including a metal core and a nickel-plating layer formed on an entire surface of the core; an upper contact portion formed on an upper surface of the body by plating the upper surface of the body with gold or a gold alloy; and a lower contact portion formed on a lower surface of the body by plating the lower surface of the body with gold or a gold alloy, wherein edges of the body extend outward more than edges of the upper contact portion, the nickel-plating layer prevents flux included in solder cream from rising along the upper contact portion during the reflow soldering, and an electrically conductive external object is electrically connected to the land pattern by bringing the object into contact with the upper contact portion.

Preferably, the circuit board may be a thin flexible printed circuit board (FPCB) or a hard or semi-rigid printed circuit board having an exposed electrical circuit formed of a copper layer.

Preferably, the electrically conductive external object may be an elastic metal connector or terminal.

Preferably, the land pattern may be divided into a pair of equal-area parts, and the land pattern may be equal to or smaller than the lower contact portion in size.

Preferably, the metal pad interface may be supplied using a carrier by reel taping, picked up by applying a vacuum to the upper contact portion, surface mounted on the land pattern of the circuit board, and reflow soldered to the land pattern of the circuit board by using solder cream.

According to the above-described configuration, since the metal pad interface covers the land pattern which is irregularly formed on the circuit board using copper for contact with an electrically conductive external object, the effect of partial plating may be obtained without a complicated plating process.

In addition, since the metal pad interface of which the outermost layer is plated with gold is soldered to the land pattern of the circuit board which is formed of copper, reliable contact with an electrically conductive object may be possible.

In addition, since the body of the metal pad interface is plated with the nickel-plating layer having high mechanical strength, reliable mechanical contact with an electrically conductive object may be possible.

In addition, the metal pad interface which is plated with gold on upper and lower surfaces thereof in give shapes may be picked up by vacuum, surface mounted on the land pattern, and reflow soldered to the land pattern to cover the land pattern, thereby improving mass productivity, simplifying manufacturing processes, and reducing material costs and manufacturing costs.

In addition, the nickel-plating layer of the body of the metal pad interface has poor solderability with respect to reflow soldering that uses solder cream, and gold or a gold alloy having high solderability is not plated on upper surface edge portions of the body. Therefore, when a reflow soldering process is performed, electrically insulative flux included in solder cream may not rise along the body, and thus reliable electrical contact may be made with an electrically conductive external object.

### BRIEF DESCRIPTION OF THE DRAWINGS

FIG. 1 illustrates a metal pad interface of the present invention.

FIG. 2A illustrates an application to a circuit board, and FIG. 2B is a side view illustrating a mounted state.

### DETAILED DESCRIPTION OF THE INVENTION

Technical terms used in the present invention are only for explaining specific embodiments while not limiting the present invention. In addition, unless otherwise defined, technical terms used in the present invention have the same meaning as commonly understood by those of ordinary skill in the art and will not be interpreted in an overly broad or narrow sense. In addition, if technical terms used in the present invention are incorrect to exactly express the idea of the present invention, the technical terms should be interpreted as terms by which those of ordinary skill in the art can correctly understand the idea of the present invention. In addition, general terms used in the present invention may be interpreted as defined in dictionaries or according to the contextual meanings, and should not be interpreted in an overly narrow sense.

Hereinafter, specific embodiments of the present invention will be described in detail with reference to the accompanying drawings.

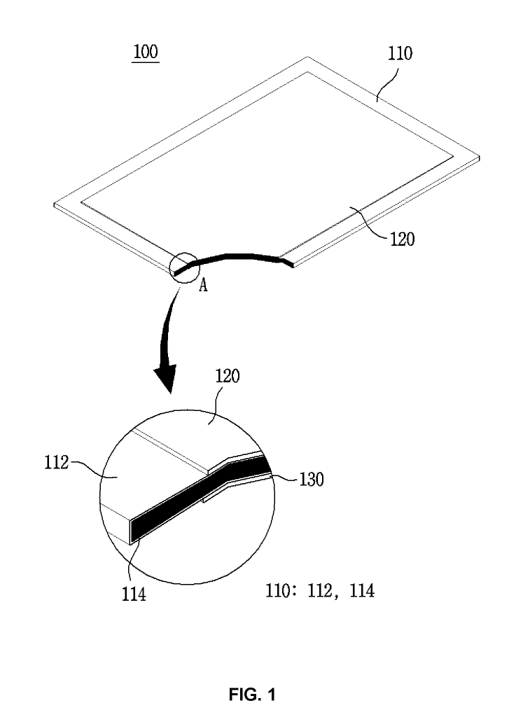

FIG. 1 illustrates a metal pad interface 100 of the present invention.

The metal pad interface 100 includes a body 110 and contact portions 120 and 130 respectively formed on upper and lower surfaces of the body 110.

Although the size of the metal pad interface 100 is not particularly limited, the metal pad interface 100 may have a size corresponding to a land pattern of a circuit board as described later. For example, the metal pad interface 100 may have a very small size: a height of about 0.12 mm, a length of about 3 mm, and a width of about 2 mm.

Referring to an enlarged circle in FIG. 1, the body 110 includes: a core 112 having a thin sheet shape and formed of copper, a copper alloy, or a stainless steel: and a nickel-plating layer 114 formed on the entire surface of the core 112.

Preferably, the core 112 is form of a high-strength copper alloy having high electrical conductivity, high strength, and high workability.

The nickel-plating layer 114 has higher strength than gold and thus has wear resistance when making elastic contact with an electrically conductive object such as an elastic metal connector or terminal.

The thickness of the nickel-plating layer 114 may be within the range of 2 microns to 10 microns, and since the nickel-plating layer 114 has poor solderability with respect to reflow soldering that use solder cream because of the nature of the material of the nickel-plating layer 114, the nickel-plating layer 114 may function as a solder flux barrier for controlling the movement of electrically insulative solder flux included in solder cream.

The upper and lower contact portions 120 and 130 may be smaller than the body 110 and may be formed through a plating process using gold or a gold alloy such as a gold-cobalt alloy.

In this case, the contact portions 120 and 130 may be formed of a gold alloy having higher strength than gold and the nickel-plating layer 114. Owing to this, reliable mechanical contact may be maintained although the contact portions 120 and 130 are repeatedly brought into contact with opposite electrical contact terminals for a long time.

The plating thickness of gold or a gold alloy may be within the range of 0.01 microns to 0.2 microns.

The upper and lower contact portions 120 and 130 may have the same shape or similar shapes, and thus processes such as a reel taping process may be easily performed. However, the upper and lower contact portions 120 and 130 are not limited thereto.

The edges of the body 110 extend outward more than the edges of the contact portions 120 and 130 such that the nickel-plating layer 114 may remain intact between the edges of the body 110 and the edges of the contact portions 120 and 130 without being plated with gold or a gold alloy.

In the above-described structure, the nickel-plating layer 114 of the body 110 of the metal pad interface 100 has poor solderability with respect to reflow soldering that uses solder cream, and gold or a gold alloy having high solderability is not plated on an upper surface of the body 110 between the edges of the body 110 and the edges of the contact portions 120 and 130. Therefore, when a reflow soldering process is performed, electrically insulative flux included in solder cream does not rise along the body 110, and thus reliable electrical contact may be made with an electrically conductive external object.

In addition, unlike the present embodiment, the lower contact portion 130 may include separate division patterns to cope with division land patterns of a circuit board as described later. In this case, disadvantageously, reel taping costs may increase because of different upper and lower surfaces.

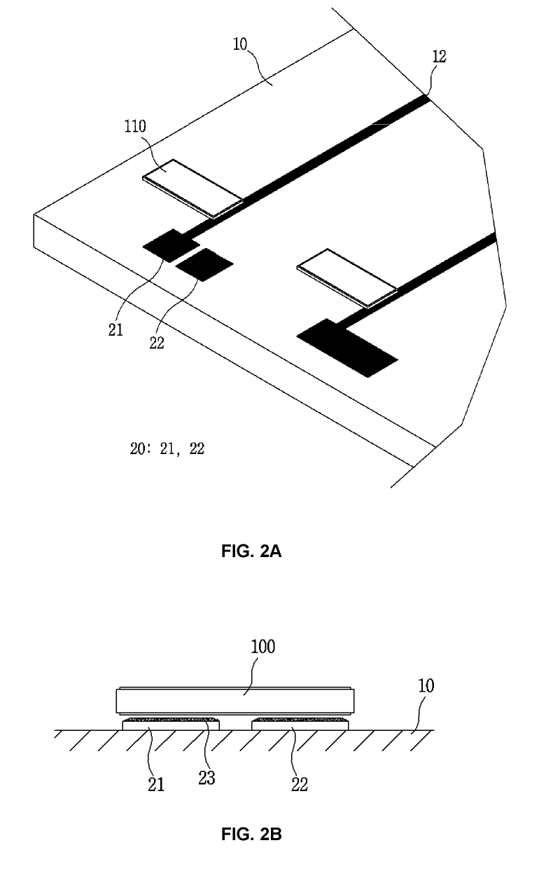

FIG. 2A illustrates an application to a circuit board 10, and FIG. 2B is a side view illustrating a mounted state.

The metal pad interface 100 is supplied using a carrier by reel taping, picked up by vacuum, surface mounted on a land pattern 20 of the circuit board 10, and then fixed to the land pattern 20 of the circuit board 10 by reflow soldering.

The circuit board 10 may be a thin flexible printed circuit board (FPCB) or may be a tin or copper plated hard or semi-rigid printed circuit board.

Referring to FIG. 2A, the land pattern 20 is formed on the circuit board 10 for electrical contact with an electrically conductive external object such as an antenna, and electronic components (not shown) are connected to the land pattern 20 through a circuit pattern 12.

In the present embodiment, the land pattern 20 is divided into two division patterns 21 and 22 such that the metal pad interface 100 may be stably placed on the land pattern 20.

In addition, the amount of solder cream 23 applied to the land pattern 20 may be reduced, and since the solder cream 23 or flux included in the solder cream 23 that is melted is allowed to flow between the division patterns 21 and 22 during reflow soldering, the situation in which molten solder rises along the metal pad interface 100 may be minimized.

Referring to FIG. 2B, the metal pad interface 100 supplied using the carrier by reel taping is picked up by vacuum and mounted on the land pattern 20.

As described above, the lower contact portion 130 of the metal pad interface 100 has a size corresponding to the land pattern 20 such that the metal pad interface 100 mounted on the land pattern 20 may cover the land pattern 20. Therefore, the land pattern 20 formed of a copper material may not be exposed to the outside, thereby preventing corrosion of the land pattern 20.

In addition, the land pattern 20 includes the two division patterns 21 and 22, and solder cream is applied to the division patterns 21 and 22.

Therefore, since some molten solder flows between the division patterns 21 and 22 during soldering, the situation in which molten solder rises along the metal pad interface 100 may be minimized. In addition, since the outer surface of the body 110 is plated with the nickel-plating layer 114, it is possible to prevent the molten solder from rising along the body 110.

As described above, the metal pad interface 100 plated with gold on upper and lower surfaces thereof is picked by vacuum, surface mounted on the land pattern 20, and reflow soldered to the land pattern 20 to cover the land pattern 20 without having to perform a partial gold plating process on the land pattern 20, thereby increasing the yield of manufacturing processes and decreasing manufacturing costs.

In addition, since the land pattern 20 is covered with the metal pad interface 100 and is thus not exposed to the outside, corrosion resistance of the land pattern 20 may be improved, and RF characteristics of an antenna or the like may be maintained.

In addition, since the body 110 of the metal pad interface 100 is plated with the nickel-plating layer 114 having high mechanical strength, reliable mechanical contact with an electrically conductive object may be provided.

In addition, since the metal pad interface 100 covers the land pattern 20 which is irregularly formed on the circuit board using a copper material for contact with an electrically conductive external object, the effect of partial plating may be obtained without a complicated plating process.

In addition, since the metal pad interface 100 of which the outermost layer is plated with gold is soldered to the land pattern 20 of the circuit board 10 which is formed of copper, reliable electrical contact with an electrically conductive object may be possible.

In addition, the nickel-plating layer 114 of the body 110 of the metal pad interface 100 has poor solderability with respect to reflow soldering that uses solder cream, and gold or a gold alloy having high solderability is not plated on upper surface edge portions of the body 110. Therefore, when a reflow soldering process is performed, electrically insulative flux included in solder cream does not rise along the body 110, and thus reliable electrical contact may be made with an electrically conductive external object.

Those of ordinary skill in the art may make changes or modifications from the above description without departing from the spirit and scope of the present invention. Therefore, the embodiments of the present invention are for illustrative purposes only and are not intended to limit the scope of the present invention. The scope of the present invention should be construed according to the appended claims, and it should be understood that all technical ideas equivalent to those described above are within the scope of the present invention.

What is claimed is:

1. A metal pad interface comprising:
a body comprising a sheet-shaped metal core and a nickel-plating layer formed on an outer surface of the core;
an upper contact portion formed on an upper surface of the body by plating the upper surface of the body with gold or a gold alloy; and
a lower contact portion formed on a lower surface of the body by plating the lower surface of the body with gold or a gold alloy,
wherein edges of the body extend outward more than edges of the upper contact portion,
wherein the lower contact portion is mounted on a land pattern of a circuit board by soldering, and the upper contact portion is brought into elastic contact with an electrically conductive external object for electrical connection between the object and the land pattern,
wherein the nickel-plating layer prevents molten solder from rising along the upper contact portion during the soldering.

2. The metal pad interface of claim 1, wherein the edges of the body extend outward more than edges of the lower contact portion.

3. The metal pad interface of claim 1, wherein the upper and lower contact portions have the same size and shape or similar sizes and shapes.

4. The metal pad interface of claim 1, wherein the upper and the lower contact portions comprise the same material.

5. The metal pad interface of claim 1, wherein the upper contact portion has greater mechanical strength than the land pattern.

6. The metal pad interface of claim 1, wherein the core comprises copper, a copper alloy, or stainless steel.

7. An electrical contact structure for a circuit board, the electrical contact structure comprising a metal pad interface which is soldered to a land pattern of the circuit board by reflow soldering,
wherein the metal pad interface comprises:
a body comprising a metal core and a nickel-plating layer formed on an entire surface of the core;
an upper contact portion formed on an upper surface of the body by plating the upper surface of the body with gold or a gold alloy; and
a lower contact portion formed on a lower surface of the body by plating the lower surface of the body with gold or a gold alloy,
wherein edges of the body extend outward more than edges of the upper contact portion,
the nickel-plating layer prevents flux included in solder cream from rising along the upper contact portion during the reflow soldering, and
an electrically conductive external object is electrically connected to the land pattern by bringing the object into contact with the upper contact portion.

8. The electrical contact structure of claim 7, wherein the circuit board is a thin flexible printed circuit board (FPCB) or a hard or semi-rigid printed circuit board having an exposed electrical circuit formed of a copper layer.

9. The electrical contact structure of claim 7, wherein the electrically conductive external object is an elastic metal connector or terminal.

10. The electrical contact structure of claim 7, wherein the land pattern is divided into a pair of equal-area parts.

11. The electrical contact structure of claim 7, wherein the land pattern is equal to or smaller than the lower contact portion in size.

12. The electrical contact structure of claim 7, wherein the metal pad interface is supplied using a carrier by reel taping, picked up by applying a vacuum to the upper contact portion, surface mounted on the land pattern of the circuit board, and reflow soldered to the land pattern of the circuit board by using solder cream.
